(19) United States
(12) Patent Application Publication
(10) Pub. No.: US 2007/0087573 A1
(43) Pub. Date: Apr. 19, 2007

(54) Pre-treatment method for physical vapor deposition of metal layer and method of forming metal silicide layer

(76) Inventors: Yi-Yiing Chiang, Taipei City (TW); Chao-Ching Hsieh, Hsinchu Hsien (TW); Tzung-Yu Hung, Sinshih Township (TW); Yu-Lan Chang, Kaohsiung City (TW); Chien-Chung Huang, Taichung Hsien (TW); Yi-Wei Chen, Dajia Township (TW)

Correspondence Address: J.C. Patents, Inc., Suite 250, 4 Venture, Irvine, CA, 92618, US

(21) Appl. No.: 11/255,420

(22) Filed: Oct. 19, 2005

(51) Int. Cl. C03C 25/68; B05D 3/00; H01L 21/302; B44C 1/22

(52) U.S. Cl. 438/715; 438/706; 427/299; 216/58

(57) ABSTRACT

A pre-treatment method for physical vapor deposition of a metal layer is provided. A substrate is first provided and then a dry cleaning process is performed to the substrate using a chemical etching process, in which the chemical etching process causes a reaction to the oxide. Thereafter, an annealing process is performed, followed by a cooling process. Due to the treatment prior to depositing of the metal layer, subsequent metal layers from ill effects are prevented.

### BACKGROUND OF THE INVENTION

1. Field of Invention

The present invention relates to a pre-treatment method for deposition of a metal layer. In particular, it relates to a pre-treatment method for physical vapor deposition (PVD) of a metal layer and a fabrication method of a metal silicide layer.

2. Description of Related Art

As the CMOS technology becomes closer to the sub-100 nm node, conventional material for metal silicide layer such as cobalt silicide is starting to reveal its process margin. At the same time, nickel silicide has become the dominant material of the next generation because of having many advantages such as, for example, reduced silicon consumption, reduced line width dependency, lower fabrication process thermal threshold, and improved compatibility with SiGe substrate. However, the prominent leakage issues for nickel silicide is yet to be resolved.

### SUMMARY OF THE INVENTION

The objective of the present invention is for providing a pre-treatment method for-the physical vapor deposition of a metal layer for preventing ill effects for the deposited metal layer.

Another objective of the present invention is for providing a fabrication method of the metal silicide layer, having reduced metal silicide layer resistivity and elimination of leakage issues for the metal silicide layer.

The present invention proposes a pre-treatment method for the physical vapor deposition of the metal layer, which includes the providing of a substrate, and the using of a chemical etching process to perform a dry cleaning process to the substrate, wherein the aforementioned chemical etching process makes the oxide to be removed from the substrate. Furthermore, an annealing process is performed, and followed by a cooling process.

According to an embodiment of the present invention for the aforementioned pre-treatment method, the reaction gas adopted by the aforementioned chemical etching process is a gas which produces a reaction with silicon oxide layer, and also can further produce a reaction with silicon nitride layer, or a gas including NF₃, NH₃, H₂, SF₆, or H₂O.

According to an embodiment of the present invention for the aforementioned pre-treatment method, the aforementioned annealing process temperature is about between 100° C. to 350° C.

According to the embodiment of the present invention for the aforementioned pre-treatment method, the aforementioned cooling process is at a temperature below 50° C. for about 5 to 60 seconds.

The fabrication method of a metal silicide layer proposed in the present invention includes the providing of a substrate and the using of a chemical etching process to perform a cleaning process for a substrate, wherein the chemical etching process produces a reaction to the oxide. Later, an annealing process is performed, and a cooling process is performed. Furthermore, a metal layer is deposited on the substrate, and the metal layer and the substrate are made to produce silicification reaction for forming a metal silicide layer. Finally, unreacted metal layer is removed.

According to an embodiment of the present invention for the fabrication method of the aforementioned metal silicide layer, the reaction gas adopted by the aforementioned chemical etching process is a gas which produces a reaction with silicon oxide layer. Going a step further, the reaction gas adopted by the chemical etching process is a gas capable of producing reaction with silicon nitride layer. The reaction gas adopted by the aforementioned chemical etching process can also be a gas such as NF₃, NH₃, H₂, SF₆, or H₂O.

According to an embodiment of the present invention for the fabrication method of the aforementioned metal silicide layer, the aforementioned temperature for the annealing process is about 100° C. to 350° C.

According to an embodiment of the present invention for the fabrication method of the aforementioned metal silicide layer, the aforementioned first cooling process is performed at a temperature of 50° C. for about 5 to 60 seconds.

According to an embodiment of the present invention for the fabrication method of the aforementioned metal silicide layer, the performing of a degas process is included before the aforementioned cleaning process is performed on the substrate.

According to an embodiment of the present invention for the fabrication method of the aforementioned metal silicide layer, a cooling process is included following the aforementioned steps for the deposition of the metal layer on the substrate.

According to an embodiment of the present invention for the fabrication method of the aforementioned metal silicide layer, the material of the aforementioned metal layer is a metal selected from titanium, cobalt, tantalum, nickel, platinum, hafnium, palladium, tungsten, molybdenum, or niobium.

Because a pre-treatment is performed prior to the deposition of the metal layer in the present invention, as a result, the metal layer would not be damaged. Therefore, when the aforementioned pre-treatment is used during the fabrication method for forming the metal silicide layer, it can reduce resistivity of the metal silicide layer and eliminate leakage issues for the metal silicide layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a procedural diagram for a pre-treatment in the physical vapor deposition of a metal layer, according to a first embodiment of the present invention.

FIG. 2A to FIG. 2D schematically illustrate the fabrication method of a metal silicide layer, according to a second embodiment of the present invention.

FIG. 3 is a block diagram of a leakage current of the metal silicide layer formed separately using a conventional method and using the method of the present invention.

FIG. 4 is a Rs block diagram of the metal silicide layer formed separately using a conventional method and using the method of the present invention.

### DESCRIPTION OF THE PREFERRED EMBODIMENTS

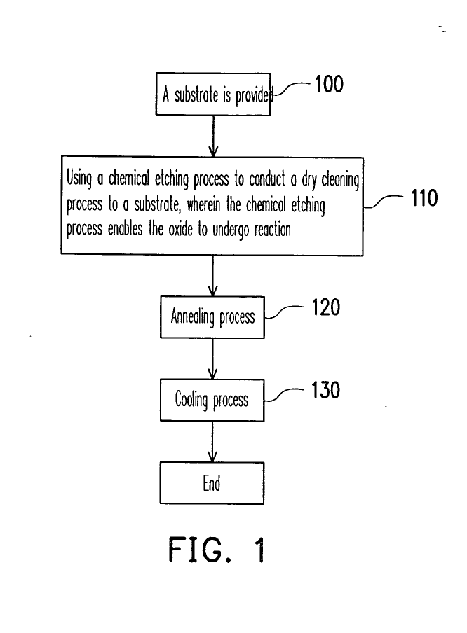

FIG. 1 illustrates the pre-treatment procedural diagram of the physical vapor deposition of the metal layer according to the first embodiment of the present invention.

Referring to FIG. 1, in the step 100, first a substrate is provided. Later, in a step 110, a chemical etching process is used to perform a dry cleaning process to the substrate, wherein the chemical etching process enables reaction for the oxide. And the reaction gas adopted by the aforementioned chemical etching process is, for example, a gas which forms a reaction with silicon oxide layer, wherein the aforementioned reaction gas further can form a reaction with silicon nitride layer or a gas including NF₃, NH₃, H₂, SF₆, or H₂O.

Later, in the step 120, an annealing process is performed, whose temperature is, for example, between 100° C. to 350° C. Later, in the step 130, a cooling process is performed. The aforementioned cooling process is performed at temperature below 50° C. for about 5 to 60 seconds.

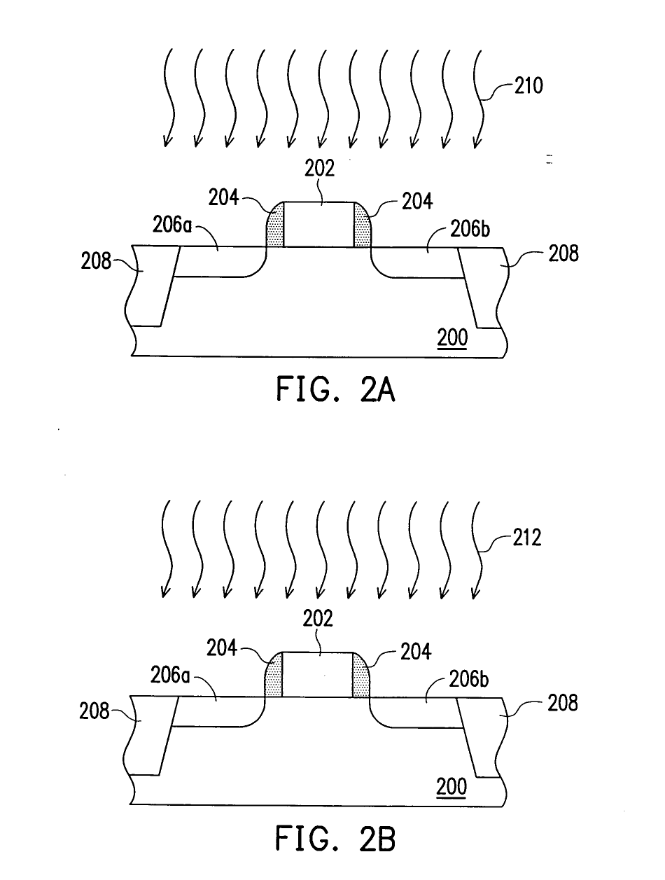

FIG. 2A to FIG. 2D illustrate the fabrication method of the metal silicide layer, according to a second embodiment of the present invention.

Referring to FIG. 2A, a substrate 200 is provided, and the substrate 200, for example, is a silicon wafer having a plurality of semiconductor devices already formed, for example, having a gate 202, a spacer 204, a source 206a, a drain 206, a isolation structure 208, and other semiconductor devices . Thereafter, a cleaning process 210 is performed using a chemical etching process for the substrate 200, wherein the chemical etching process produces a reaction for the oxide. For example, the reaction action adopted by the aforementioned chemical etching process is a gas, for example, which produces reaction with silicon oxide layer, and the reaction gas can further be a gas capable of reaction with silicon nitride layer, or is a gas including NF₃, NH₃, H₂, SF₆, or H₂O. For example, when using NF₃ and NH₃ formed gas mixture as the reaction gas adopted in the chemical etching process, the chemical reaction mechanism is as follows:
NF₃+NH₃→NH₄F+NH₄F.HF
NH₄F+NH₄F.HF+SiO₂→(NH₄)₂SiF₆₍ₛ₎+H₂O
(NH₄)₂SiF₆.Si→Si+(NH₄)₂SiF₆↑

After the cleaning process 210, it eliminates the factors of having oxides on the surface of the substrate 200 or factors that affect subsequent deposition of the metal layer. Before the cleaning process 210 is performed, a degas process can first be performed.

Later, referring to FIG. 2B, an annealing process 212 is performed. And the temperature for the annealing process is, for example, between 100° C. to 350° C., for making the substrate 200 surface, in the aforementioned chemical etching process, to produce side products which are to be vaporized.

Later, referring to FIG. 2C, a first cooling process 214 is performed, and is, for example, performed at temperature below 50° C. for about 5 to 60 seconds, to regain the substrate 200 surface temperature.

Furthermore, referring to FIG. 2D, a metal layer 216 is deposited on the substrate 200. The material is a metal such as, for example, titanium, cobalt, tantalum, nickel, platinum, hafnium, palladium, tungsten, molybdenum, or niobium. In addition, a second cooling process is typically included after the step of deposition of the metal layer 216 on the substrate 200, to allow the substrate 200 to go back to the original temperature. Later, the metal layer 216 and the substrate 200 are made to form silification reactions to form a metal silicide layer 218. For example, the metal silicide layer 218 is to form on a gate 202 containing silicon, on a source 206a, and on a drain 206b surface in the substrate 200. Finally, the unreacted metal layer 216 is removed.

To prove the effectiveness of the present invention, the following proposes a comparative experimental diagram of the nickel silicide layer formed, according to the second embodiment of the present invention, and the nickel silicide layer formed in the pre-treatment using argon, according to a conventional method.

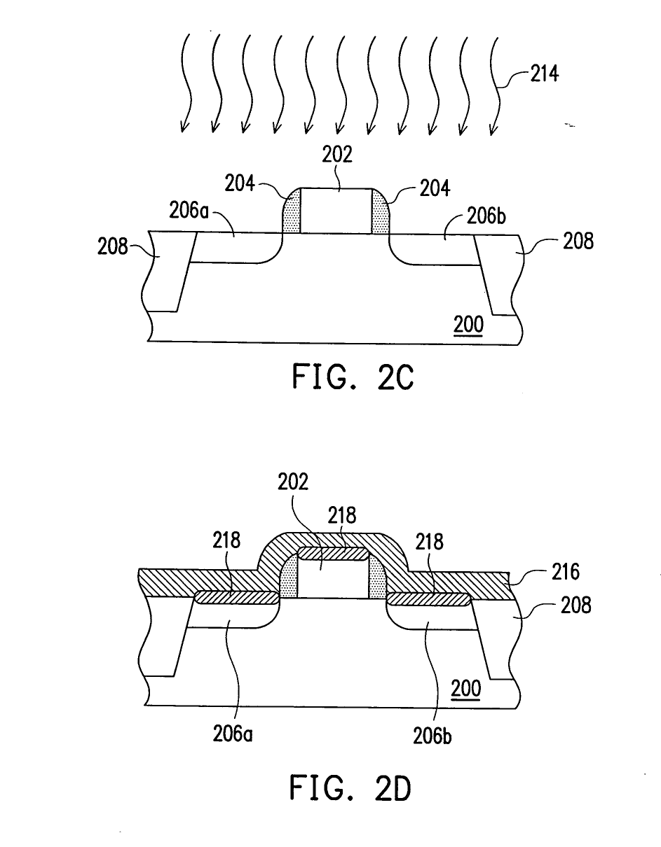

FIG. 3 is a block diagram of leakage current for the conventional method and for the method in the present invention for forming the metal silicide layer, wherein the conventional method is referred to the cleaning process using argon sputtering etching. “The present invention 1” and “the present invention 2” are both methods in accordance to the present invention, where the only difference for “the present invention 1” is the use of high temperature RCA solution and diluted hydrofluoric acid for processing the substrate prior to the cleaning process, whereas “the present invention 2” skips the aforementioned steps. From FIG. 3, the method of the present invention can be observed that the leakage for the formed nickel silicide layer is much lower than that for the nickel silicide layer formed by the conventional pre-treatment using argon sputtering etching.

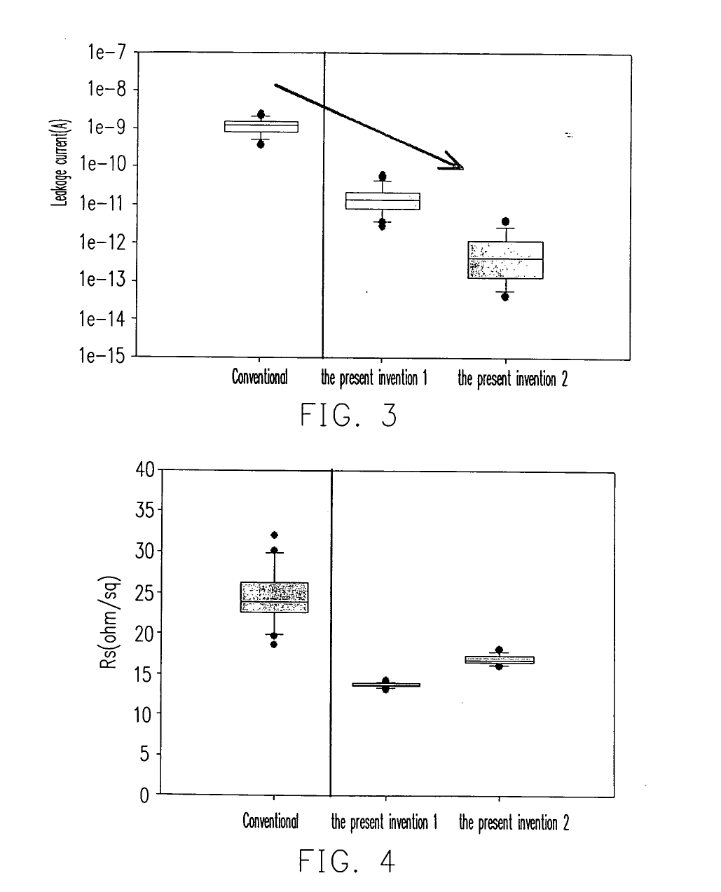

FIG. 4 is a block diagram of Rs of the metal silicide layer formed separately by the conventional method and by the method in the present invention, wherein the conventional method is the same as in FIG. 3 in reference to the cleaning process using argon sputtering etching. “The present invention 1” and “the present invention 2” are both methods according to the present invention. From FIG. 4, it can be seen that the Rs of the nickel silicide layer formed in the methods of the present invention is lower than that of the conventional method.

In summary, pre-treatment is performed on the substrate using a chemical etching process prior to the deposition of the metal layer in the present invention for allowing the remained oxide on the substrate to undergo reduction, for allowing the metal layer to be unaffected, and thus when the pre-treatment is applied during the fabrication of the metal silicide layer, the resistivity of the metal silicide layer can be greatly reduced and the leakage issues for the metal silicide layer are eliminated.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A pre-treatment method for physical vapor deposition of a metal layer, comprising:
providing a substrate;
using a chemical etching process for performing a dry cleaning process to the substrate, wherein the chemical etching process is to produce reaction to the oxide;
performing an annealing process; and
performing a cooling process.

2. The pre-treatment method for the physical vapor deposition of the metal layer according to claim 1, wherein the reaction gas adopted by the chemical etching process is a gas which produces reaction with silicon oxide layer.

3. The pre-treatment method for the physical vapor deposition of the metal layer according to claim 2, wherein the reaction gas adopted by the chemical etching process is a gas which produces reaction with silicon nitride layer.

4. The pre-treatment method for the physical vapor deposition of the metal layer according to claim 2, wherein the reaction gas adopted by the chemical etching process includes a gas of NF₃, NH₃, H₂, SF₆, or H₂O .

5. The pre-treatment method for the physical vapor deposition of the metal layer according to claim 1, wherein the temperature of the annealing process is between 100° C. to 350° C.

6. The pre-treatment method for the physical vapor deposition of the metal layer according to claim 1, wherein the cooling process is performed at a temperature below 50° C. for 5 to 60 seconds.

7. A fabrication method of a metal silicide layer, comprising:
providing a substrate;
using a chemical etching process for performing a cleaning process to the substrate, wherein the chemical etching process produces reaction to an oxide;
performing an annealing process;
performing a first cooling process;
depositing a metal layer on the substrate;
forming silification reaction on the metal layer and the substrate for forming a metal silicide layer; and
removing the metal layer which is unreacted.

8. The fabrcation method of the metal silicide layer according to claim 7, wherein the reaction gas adopted by the chemical etching process is a gas which produces reaction with silicon oxide layer.

9. The fabrcation method of the metal silicide layer according to claim 8, wherein the reaction gas adopted by the chemical etching process is a gas which produces reaction with silicon nitride layer.

10. The fabrcation method of the metal silicide layer according to claim 8, wherein the reaction gas adopted by the chemical etching process includes a gas of NF₃, NH₃, H₂, SF₆, or H₂O.

11. The fabrcation method of the metal silicide layer according to claim 7, wherein the temperature of the annealing process is between 100° C. to 350° C.

12. The fabrcation method of the metal silicide layer according to claim 7, wherein the first cooling process is performed at a temperature below 50° C. for 5 to 60 seconds.

13. The fabrcation method of the metal silicide layer according to claim 7, wherein the performing of a degas process is included prior to the step of the cleaning process using the chemical etching process to the substrate.

14. The fabrcation method of the metal silicide layer according to claim 7, wherein a second cooling process is performed after the step for the deposition of the metal layer on the substrate.

15. The fabrcation method of the metal silicide layer according to claim 7, wherein the material of the metal layer is selected from titanium, cobalt, tantalum, nickel, platinum, hafnium, palladium, tungsten, molybdenum, or niobium.
